(19) United States
(12) Patent Application Publication
(10) Pub. No.: US 2009/0249999 A1
(43) Pub. Date: Oct. 8, 2009

(54) REUSABLE CRUCIBLES AND METHOD OF MANUFACTURING THEM

(75) Inventors: Rune Roligheten, Porsgrunn (NO); Gjertrud Rian, Skien (NO); Stein Julsrud, Skien (NO)

Correspondence Address: BIRCH STEWART KOLASCH & BIRCH, PO BOX 747, FALLS CHURCH, VA, 22040-0747, US

(73) Assignee: REC SCANWAFER AS, Porsgrunn (NO)

(21) Appl. No.: 12/306,503

(22) PCT Filed: Jun. 20, 2007
(86) PCT No.: PCT/NO2007/000220

§ 371 Date: Mar. 17, 2009

Related U.S. Application Data
(60) Provisional application No. 60/815,861, filed on Jun. 23, 2006.

(51) Int. Cl. C30B 19/00; B29D 31/00; C01B 21/068

(52) U.S. Cl. 117/223; 156/242; 423/344

(57) ABSTRACT

This invention relates to reusable crucibles for production of ingots of semiconductor grade silicon made of nitride bonded silicon nitride (NBSN). The crucibles may be made by mixing silicon nitride powder with silicon powder, forming a green body of the crucible, and then heating the green body in an atmosphere containing nitrogen such that the silicon powder is nitrided forming the NBSN-crucible. Alternatively the crucibles may assembled by plate elements of NBSN-material that are to be the bottom and walls of a square cross-section crucible, and optionally sealing the joints by applying a paste comprising silicon powder and optionally silicon nitride particles, followed by a second heat treatment in a nitrogen atmosphere.

This invention relates to reusable crucibles for production of ingots of semiconductor grade silicon, including solar grade silicon, and to a method for manufacturing the reusable crucibles.

### BACKGROUND

The world supplies of fossil oil are expected to be gradually exhausted in the following decades. This means that our main energy source for the last century will have to be replaced within a few decades, both to cover the present energy consumption and the coming increase in the global energy demand.

In addition, many concerns are raised that the use of fossil energy increases the earth greenhouse effect to an extent that may turn dangerous. Thus the present consumption of fossil fuels should preferably be replaced by energy sources/carriers that are renewable and sustainable for our climate and environment.

One such energy source is solar light, which irradiates the earth with vastly more energy than the present day consumption, including any foreseeable increase in human energy consumption. However, solar cell electricity has up to date been too expensive to be competitive with nuclear power, thermal power etc. This needs to change if the huge potential of the solar cell electricity is to be realised.

The cost of electricity from a solar panel is a function of the energy conversion efficiency and the production costs of the solar panel. Thus one strategy for reducing the costs of solar cell electricity is decreasing the production costs of solar wafer ingots.

The dominating process route for silicon based solar panels of multicrystalline wafers are presently by forming ingots by directional solidification by use of the Bridgman method or by related techniques, and then saw the ingots to smaller blocks and further to wafers. A main challenge in these processes is to maintain the purity of the silicon raw material and to obtain a sufficient control of the temperature gradients during the directional solidification of the ingots in order to obtain satisfactory crystal qualities.

The problem with contamination is strongly connected to the crucible material since the crucible is in direct contact with the molten silicon, and the problem with temperature control means use of slow heat extraction rates and thus long solidification times. The material of the crucibles should therefore be as chemically inert as possible towards molten silicon and withstand high temperatures up to about 1500° C. for relatively long periods.

### PRIOR ART

Silica, SiO₂, is presently the preferred material for crucible and mould applications due to availability in high purity form. When employed for directional solidification methods, the silica is wetted by the molten silicon, leading to a strong adherence between the ingot and the crucible. During cooling of the ingot, the strong adherence leads to cracking of the ingot due to build-up of mechanical tension resulting from the higher coefficient of thermal expansion of the silicon as compared to silica.

The problem with cracking of the ingots may be solved by applying a release coating of silicon nitride that resists wetting by the melt.

During the furnace process, the silica crucible is transformed from a glassy to a crystalline phase. During cooling, the crystalline SiO₂ undergoes a phase transition that causes breakage. For this reason, the silica crucibles may only be used once. This gives a significant contribution to the production costs of the ingots.

It has therefore been attempted to find crucibles that may be reused as crucible or mould for directional solidification of semiconductor grade silicon. Such a crucible need to be made of a material that is sufficiently pure and chemically inert towards the molten silicon to allow high-purity ingots being formed, and which has a thermal expansion that does not lead to the strong mechanical tensions between ingot and crucible during cooling.

One such attempt is known from JP-59-162199, which discloses crucibles made by reaction bonded silicon nitride (RBSN). Silicon nitride crucibles may be designed to give crucibles with low coefficients of thermal expansion comparable to the silicon metal. The crucibles according to JP-59-162199 were reported to have a density of 85% of theoretical maximum density of silicon nitride and they showed good mechanical strength. There was however a problem with wetting by the liquid silicon and consequently a strong adherence between the ingot and crucible, leading to cracking and breakage of the crucibles when releasing the silicon metal.

The problem with the wetting by liquid silicon is solved in NO 317 080 which discloses a crucible made of RBSN where the particle size distribution of the silicon particles and pressure during nitriding are regulated to give a silicon nitride with density between 40 and 60% of the theoretical maximum density and at least 50% of the pores of the crucible surface must have larger diameter than the mean particle size of the Si₃N₄-particles. This material is reported to show no tendency of being wetted by the liquid metal, allowing a relatively easy release of the ingot from the crucible. The crucible according to NO 317 080 was formed in one piece and given a typical cylindrical beaker-design with tapered inner surface with inner diameter from 25 to 30 mm and outer diameter of 40 mm. The height of the crucible was 40 mm.

Another example of reusable crucibles are disclosed in US application 2004-0211496 to Khattak et al. The application teaches use of square cross-section crucibles made of reaction bonded silicon nitride or isopressed silicon nitride coated with a release coating. The RBSN crucibles were made with inner cross-sectional area up to 40×40 cm². The wall thickness was about 20 mm. The isopressed crucible had inner dimensions of 17×17×17 cm³ and wall thickness of 2 cm. It was demonstrated that the crucibles could withstand 16 runs of ingot production.

Reaction bonded silicon nitride is a material that are typically made by;
mixing a silicon particle feedstock of suitable grain size distribution and purity, for example in an aqueous slip,
forming the silicon particle mixture to the desired shape, often called a green body, for example by casting in plaster moulds, and
heating the green body in a nitrogen atmosphere in a chamber furnace, a continuous furnace, or the like, thus converting the silicon in the green body to silicon nitride according to reaction (I).

3Si(s)+2N₂(g)=Si₃N₄(s) (I)

A feature of RBSN-process is that the green body undergoes only a slight dimensional change during nitriding. Another feature is that the nitriding of the silicon particles according to reaction (I) is strongly exothermic.

The strongly exothermic reaction causes problems in that hot areas in the charge will tend to react faster than surrounding material, leading to a risk of local thermal runaway. If thermal runaway occurs, there is a high probability of cracks and flaws in the material. The problem with thermal runaway sets practical limits to the physical dimensions of the objects that are to be formed, since the objects should have relatively thin bulk phases (high aspect ratios and thin walls) in order to allow a sufficient heat transport from the reaction zone during nitriding.

The RBSN-process is therefore not suited for producing crucibles for industrial scale production of semiconductor silicon, such as for instance in present day direct solidification furnaces (DS-furnaces) which forms ingots of sizes up to 100×100×40 cm³ or more. This requires crucibles with larger dimensions than presently available in RBSN-materials.

### OBJECTIVE OF THE INVENTION

The main objective of the invention is to provide a reusable crucible for production of high-purity ingots of semiconductor grade silicon.

A further objective of the invention is to provide a method for manufacturing the crucibles.

The objective of the invention may be realised by the features as set forth in the description of the invention below, and/or in the appended patent claims.

### DESCRIPTION OF THE INVENTION

The invention is based on the realisation that the problem with up-scaling of silicon nitride crucibles with sufficient purity and mechanical strength to be used for repeated cycles of melting and directionally solidifying high purity silicon metal for forming ingots with dimensions of 100×100×40 cm³ or more, may be solved by manufacturing the crucibles of nitride bonded silicon nitride (NBSN) and by forming plate elements of the NBSN-materials forming bottom and wall elements that are subsequently mounted to form the crucibles.

Thus in a first aspect of the invention there is provided a method for production of crucibles for production of ingot of semiconductor grade silicon by directional solidification, comprising
mixing silicon nitride powder with silicon powder,
forming a green body with the desired shape of the powder mixture,
heating the green body in a nitrogen atmosphere, thus converting the green body to a nitride bonded silicon nitride (NBSN) body by nitriding the silicon particles in the green body according to reaction (I).

3Si(s)+2N₂(g)=Si₃N₄(s) (I)

In a second aspect of the invention there is provided a method for production of crucibles for production of ingot of semiconductor grade silicon by directional solidification, comprising
mixing silicon nitride powder with silicon powder,
forming a set of green bodies in the form of plates that are to be the bottom and walls of a square cross-section crucible,
heating the green bodies in a nitrogen containing atmosphere, thus converting the green bodies to nitride bonded silicon nitride (NBSN) plate elements by nitriding the silicon particles in the green body and the sealing paste according to reaction (I), and
mounting the plate elements to form a crucible with square cross-sectional area.

Alternatively, the green body plate elements may assembled to form a green body crucible, and then heat the green body crucible in a nitrogen containing atmosphere until the green body crucible is nitrided into a nitride bonded silicon nitride crucible.

The crucible may be reinforced and the joints sealed by applying a paste comprising silicon powder and optionally silicon nitride particles, and then heat treat the paste in a nitrogen containing atmosphere until the silicon particles of the paste becomes nitrided and transforms the paste to a solid bonding and sealing NBSN-phase. The paste may be applied before nitriding the green bodies or after an initial nitriding of the green bodies. In the latter case, the paste will be nitrided in a second heat treatment.

In a third aspect of the invention, there is provided crucibles for production of ingot of semiconductor grade silicon by directional solidification, in which the crucibles are made of nitride bonded silicon nitride (NB SN) according to the method as specified in the first aspect of the invention.

In a fourth aspect of the invention, there is provided crucibles for production of ingot of semiconductor grade silicon by directional solidification, in which the crucibles are made of nitride bonded silicon nitride (NBSN) plate elements that are mounted to form a square cross-sectional crucible according to the method as specified in the second aspect of the invention.

The term “nitriding” as used herein means any process where a shaped powder or paste comprising silicon metal particles are heat treated in a nitrogen atmosphere until a reaction between the silicon particles and nitrogen gas is obtained such that the silicon particles are converted to silicon nitride particles, and thus obtaining a bonding of the powder mixture constituents together to form a solid body. The formed solid object will exhibit a degree of porosity depending on the particle size and particle size distribution of the silicon particles and/or other particles present in the powder before nitriding. In nitride bonded silicon nitride, the powder mixture comprises silicon particles and silicon nitride particles, and the nitriding results in that the silicon particles are converted to silicon nitride particles which bond themselves and the originally present nitride particles together to a solid porous body of pure silicon nitride.

The term “green body” as used herein means any shaped object of the powder mixture comprising silicon particles and silicon nitride particles, from dry pressed powder mixtures containing only silicon and silicon nitride powder to shaped objects consolidated from aqueous or non aqueous suspensions or slips by slip casting, gel casting or any other ceramic shaping method, and which on heating in a nitrogen atmosphere will undergo a nitriding reaction to form a solid object of porous silicon nitride with sufficient purity and mechanical strength to function as crucible material for directional solidification of semiconductor grade silicon. The green body may optionally contain additives such as binding agents, dispersants and plasticizers provided these are essentially completely volatilized during the subsequent processing.

The term “nitride bonded silicon nitride (NBSN)” as used herein means a more or less porous solid silicon nitride material consisting of an aggregate phase reflecting the particle size distribution and purity of a silicon nitride aggregate, and a bonding phase reflecting the particle size distribution and purity of a silicon powder, and where the silicon bonding phase is in essence completely converted to silicon nitride during the nitriding process.

A main distinction of NBSN-material from other silicon nitride material types is the method of preparation. A distinction from RBSN (reaction bonded silicon nitride) is that in RBSN-production, the green body is entirely made from silicon powder.

The crucibles according to the invention may advantageously be equipped with a tapering in order to ease the release of the ingot. The crucible can optionally be coated with some material to ease the release of the ingot after casting.

The sealing paste may be the same paste as the green body forming paste, an aqueous paste of silicon particles and silicon nitride particles. Alternatively the sealing paste may be a paste of only silicon particles.

It is important to employ raw materials of high purity. This is especially important for oxygen, since the oxygen content in silicon nitride is known to lead to wetting by the liquid silicon. Standard available commercial grades of silicon nitride particles may need to be purified before being applied as raw material for the green bodies according to the invention. This might be obtained by acid leaching, for instance by acid leaching and subsequent rinsing in high purity water, such as disclosed in WO 2007/045571. However, the invention is not linked to this cleaning method; any known process for providing high purity silicon nitride particles and/or silicon particles may be applied.

Compared to the RSBN-process, the process for producing crucibles of nitride bonded silicon nitride (NBSN) has the following advantages:
Better process stability. The nitriding reaction (I) is strongly exothermic. This means that hot areas in the charge will tend to react faster than surrounding material, leading to a risk of local thermal runaway. If thermal runaway occurs, there is a high probability of cracks and flaws in the material. In NBSN, the amount of material to be nitrided is less than in RBSN. This means that less heat is liberated by the reaction, and more material can absorb and distribute the heat. The result is that the process stability is significantly improved.
More flexible in engineering of microstructure. The nitriding reaction forms a product layer on the surface of the silicon particles. For the reaction to run to completion, nitrogen has to diffuse through this layer. This imposes a practical upper limit of the silicon particle size. If desired, coarse silicon nitride particles can be introduced in NBSN through the silicon nitride raw material.
Higher reliability. A crucible made from NBSN has the advantage that it can more reliably and with higher yield be made in the required dimensions for use in directional solidification of silicon due to the reduced amount of heat released by the nitriding reaction.

The plate-based process according to the second or fourth aspect of the invention has the following advantages:
The available space in the furnace is more efficiently used if plates are stacked for nitriding
Easier handling of green parts than a green crucible allows reduction of wall and bottom thickness. This improves the thermal characteristics of the crucible and saves material.
The production of the crucible made from a plate will be easier and more economical due to a lower failure rate in the casting step and a higher density of material in the furnace and the possibility for higher reaction rates during nitriding.
The final nitriding of the sealing can be quite rapid and combined with a temperature shock treatment for quality control.

### LIST OF FIGURES

FIG. 1, part a) to c) is a schematic view of plate elements that may be assembled to form a crucible for DS-solidification of silicon according to one embodiment of the invention. FIG. 1 d) illustrates the assembled crucible.

FIG. 2 part a) and b) is a schematic view of plate elements that may be assembled to form a crucible for DS-solidification of silicon according to a second embodiment of the invention. FIG. 2 c) illustrates the assembled crucible.

### EXAMPLE OF AN EMBODIMENT OF THE INVENTION

The invention will be described in further detail by way of examples of embodiments of the invention according to the second or fourth aspect of the invention, production of plate elements that assembled to form a square cross-sectional reusable crucibles. These examples should by no means be considered to represent a limitation of the general inventive concept of forming reusable crucibles of nitride bonded silicon nitride, NBSN, any conceivable shape and dimensions of NBSN elements, in one piece or assembles by several pieces, that may function as crucible for solidifying silicon may be employed.

The plate elements in the crucible according to example 1 and 2 are all made by casting a slurry of >60 weight % silicon nitride particles and <40 weight % Si particles into a mould, preferably made from plaster with the net shape of plate element that is to be formed, including grooves and apertures in order to obtain plates suitable for assembly into crucibles. Then the plates are heated in an atmosphere of essentially pure nitrogen up to a temperature above 1400° C. during which the silicon in the as cast material will react and form silicon nitride bonds between the silicon nitride grains and evaporate additives. The heat treatment in a nitrogen atmosphere is continued until all Si-particles in the slurry have been nitrided such that solid plates of silicon nitride is obtained. If necessary, the nitrided plates may be polished and shape-trimmed after cooling for obtaining accurate dimensions, and thus allowing forming tight and leak proof crucibles upon assembly.

When assembling the crucibles, a sealing paste made from silicon dispersed in a liquid is deposited on the areas of the plate elements that will be in contact with adjacent plate elements when assembled. Then the plate elements are assembled, and the formed crucible is subject to a second heat treatment in an atmosphere of essentially pure nitrogen atmosphere such that the Si-particles of the sealing paste is nitrided and thus sealing the joints of the crucible and bonding the elements together. The second heat treatment is similar to the first, at about 1400° C. and a duration which nitrides all Si-particles in the sealing paste.

### Example 1

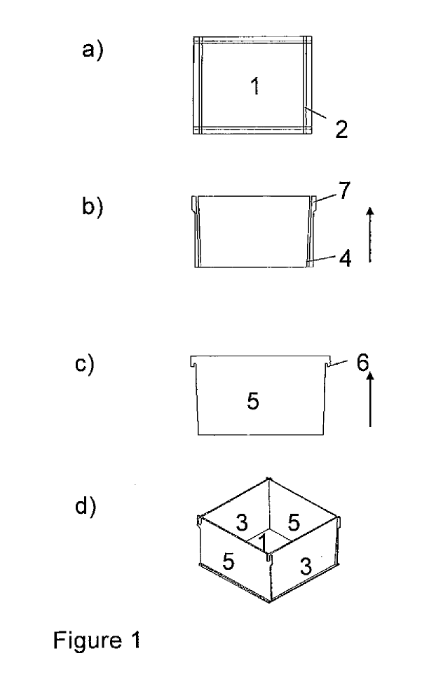

FIG. 1 is a schematic view of the plate elements forming the bottom and side-walls of a square cross-sectional crucible according to a first example of the invention. All elements are made of NBSN. The figure also shows the assembled crucible.

FIG. 1a illustrates the bottom plate 1, which is a quadratic plate with a groove 2 on the upward facing surface along each of its sides. The grove is fitted to the thickness of the side elements forming the walls of the crucible such that the lower edge of the side walls enters into the groove and forms a tight fit. Alternatively, the side elements and the bottom groove may be given a complementary shape such as e.g. a plough and tongue.

FIG. 1b shows one rectangular wall element 3. There will be used two of these at opposing sides, see FIG. 1d. The side element 3 is equipped with a groove 4 along both edges on the surface facing inwards into the crucible. The grooves 4 are dimensioned to give a tight fit with the side edges of the wall elements 5 placed perpendicularly on the wall elements 3. The grooves 4 and side edges of the wall elements 3 may be given an congruent angled orientation such that the wall element becomes shaped as an isosceles trapezium where the bottom and upper side edges are parallel and the side edges are forming congruent angles. This isosceles trapezium make the assembled crucible tapered such that the cross sectional area of the opening of the crucible is larger than the cross sectional area of the bottom of the crucible. The upper direction is indicated by the arrow in FIG. 1b. Also, at the upper part of the side edges, the wall element 3 may be equipped with a protrusion 7 which may form a locking grip with a corresponding protrusion 6 on wall element 5, see FIG. 1d.

FIG. 1c shows the corresponding wall element 5 of the crucible according to the first example of the invention. There will be used two of these wall elements at opposing sides and perpendicularly between the wall elements 3, see FIG. 1d. The wall elements 5 is at the upper sides equipped with a protrusion 6, that is given a complementary shape as the protrusions 7 of the walls 3. The protrusions 6, 7 will form a locking grip when the protrusion 6 is thread into protrusion 7.

FIG. 1d illustrates the plate elements when assembled into a crucible. The sealing paste is applied in each groove 2, 4 before assembly. If the grooves 2, 4 and edges of the plate elements 3, 5 are given a sufficient dimensional accuracy, the crucible may be assembled with a sufficient tight fit to obtain a leak proof crucible. In this case, the use of sealant paste and second heating may be omitted, the wall elements will be held in place by the protrusions 6, 7.

### Example 2

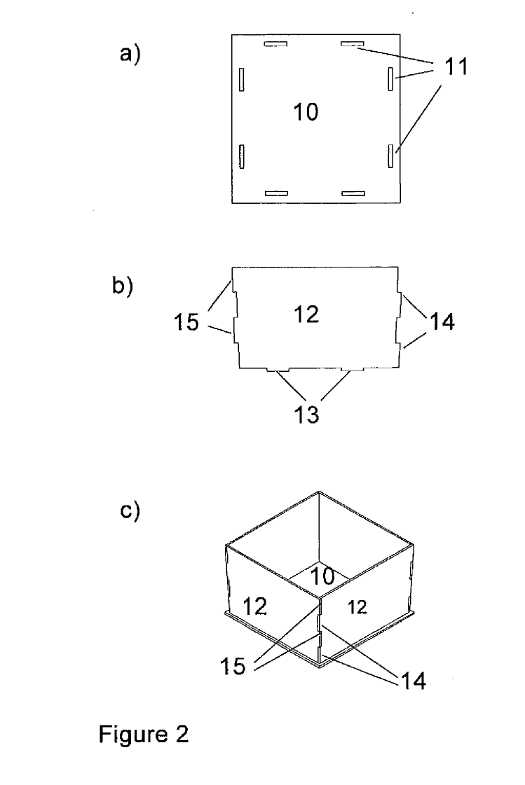

FIG. 2 is a schematic view of the plate elements forming the bottom and side-walls of a square cross-sectional crucible according to a second example of the invention. All elements are made of NBSN. The figure also shows the assembled crucible.

FIG. 2a illustrates the bottom plate 10, which is a quadratic plate with two elongated apertures 11 along each of its sides. The dimensions of the apertures are fitted such that they can receive a downward facing protrusion of the side walls and form a tight fit. It is also envisioned to include grooves (not shown) running aligned with the centre axis of the apertures 11, similar to the grooves 2 of the bottom plate 1 of the first example.

FIG. 2b shows one wall element 12. There will be four of these elements, see FIG. 2c. The side element 12 is equipped with two protrusions 14, 15 on each side and two downward protrusions 13. The side protrusions are dimensioned such that the protrusions 14 enter the space between the protrusions 15 and form a tight fit when two wall elements 12 are assembled forming adjacent walls of the crucible. The downward facing protrusions 13 are dimensioned to fit into the apertures 11 and form a tight fit, see FIG. 2c. The side edges of the wall elements 12 may be given an congruent angled orientation such that the wall element becomes shaped as an isosceles trapezium where the bottom and upper side edges are parallel and the side edges are forming congruent angles. This isosceles trapezium make the assembled crucible tapered such that the cross sectional area of the opening of the crucible is larger than the cross sectional area of the bottom of the crucible. The upward direction is indicated by the arrow in FIG. 2b.

FIG. 2c illustrates the plate elements 10, 12 when assembled into a crucible. The sealing paste is applied on each side edge and the lower edge of each wall element 12 before assembly.

This example should not be considered bounded to use of two protrusions 13, 14, 15 on each side edge and bottom of the wall elements 12. Any conceivable number of protrusions 13, 14, 15 from 1 and upwards may be employed.

1-15. (canceled)

16. Method for manufacturing crucibles intended for production of ingot of semiconductor grade silicon by directional solidification,
characterised in that it comprises:
mixing silicon nitride powder with silicon powder,
forming a green body with the desired shape of the powder mixture, and
heating the green body in an atmosphere of substantially pure nitrogen, thus converting the green body to a nitride bonded silicon nitride (NBSN) body by nitriding the silicon particles in the green body according to the reaction: 3 Si (s)+2 N₂ (g) Si₃N₄ (s).

17. Method according to claim 16,
characterised in that it comprises:
mixing silicon nitride powder with silicon powder,
forming a set of green bodies in the form of plates that are to be the bottom and walls elements of a square cross-section crucible,
heating the green bodies in a nitrogen containing atmosphere, thus converting the green bodies and to solid nitride bonded silicon nitride (NBSN) plate elements by nitriding the silicon particles in the green bodies according to the reaction: 3 Si (s)+2 N₂ (g)=Si₃N₄ (s), and
mounting the bottom and wall elements to form a crucible with square cross-sectional area.

18. Method according to claim 17,
characterised in that the green bodies in the form of plates are mounted to form a green body of the crucible before heating in the nitrogen containing atmosphere until the green body is converted to a crucible consisting of nitride bonded silicon nitride (NBSN).

19. Method according to claim 17,
characterised in that a sealing paste is applied for sealing or optionally bonding the joints of the plate elements when assembling the crucible.

20. Method according to claim 19,
characterised in that the sealing paste is a paste comprising silicon powder and optionally silicon nitride particles, which will form a solid sealing and optionally bonding phase of solid nitride bonded silicon nitride when heated in a nitrogen containing atmosphere.

21. Method according to claim 16,
characterised in that
the powder mixture comprises more than 60 weight % silicon nitride particles and less than 40 weight % silicon particles,
the powder mixture is formed to an aqueous paste by adding high purity water, and
that the green bodies formed of the aqueous slurry are heated in an atmosphere of essentially pure nitrogen up to a temperature above 1400° C.

22. Method according to claim 16,
characterised in that the green body is a shaped body of the silicon nitride powder and silicon powder mixture by use of one of the following: dry pressed powder mixtures containing only silicon and silicon nitride powder, or shaped objects consolidated from aqueous or non aqueous suspensions or slips by slip casting, gel casting or any other ceramic shaping method.

23. Method according to claim 22,
characterised in that the green body may optionally contain additives such as binding agents, dispersants and plasticizers.

24. Crucibles intended for production of ingot of semiconductor grade silicon by directional solidification,
characterised in that it is made by the method of claim 17.

25. Crucible for direct solidification of silicon,
characterised in that
the crucible is formed by assembling one bottom plate element (1, 10) and four wall elements (3, 5, 12) all made of nitride bonded silicon nitride (NBSN) defining a square cross sectional crucible, and
the joints between adjacent wall elements (3, 5, 12) and between the wall elements (3, 5, 12) and bottom element (1, 10) are sealed and locked by applying a silicon containing sealant paste before assembly and then heated in a substantially pure nitrogen atmosphere to form a solid sealing/bonding phase of silicon nitride of the paste.

26. Crucible according to claim 25,
characterised iii that the one bottom plate element (1, 10) and four wall elements (3, 5, 12) are mounted before when they are green bodies, and thus form a green body shaped as the crucible, and then subject the green body of the crucible for the nitridation process forming the crucible made of nitride bonded silicon nitride (NBSN.

27. Crucible according to claim 25,
characterised in that
the crucible is assembled using one bottom plate (1), two side walls (3), and two side walls (5) in an intermittent sequence,
the bottom plate (1) is a quadratic plate with a groove (2) along each side edge on the upward facing surface, and where the grooves (2) are fitted such that lower edge of the side walls (3, 5) enters into the grooves (2) and forms a tight fit, and
the wall elements (3) are equipped with a groove (4) along both edges on the surface facing inwards into the crucible, which are dimensioned to give a tight fit with the side edges of the wall elements 5.

28. Crucible according to claim 26,
characterised in that
the grooves (4) and side edges of the wall elements (3) are given an congruent angled orientation such that the wall element becomes shaped as an isosceles trapezium where the bottom and upper side edges are parallel and the side edges are forming congruent angles,
the wall elements (3) are equipped with a protrusion (7),
the wall elements (5) are equipped with a protrusion (6), and
the protrusions (6, 7) are shaped such that the form a locking grip holding two side elements (3, 5) tightly together when assembling the enicible.

29. Crucible according to claim 27,
characterised in that the wall elements (3, 5) and bottom element (1) are assembled without use of sealing paste.

30. Crucible according to claim 25,
characterised in that
the crucible is assembled using one bottom plate (10) and four side walls (12),
the bottom plate (10) is a quadratic plate with two apertures (11) along each side edge on the upward facing surface,
the wall elements (12) are equipped with two downward facing protrusions (13) fitted to enter the aperture (11) and form a tight fit with bottom element (10), two side protrusions (14) on one side edge and two protrusions (15) on the other side edge, and
where the protrusions (14, 15) are dimensioned such that the protrusion (14) enters the space between the protrusions (15) and forms a tight fit when two wall elements (12) are assembled forming adjacent walls of the crucible.

31. Method according to claim 18,
characterised in that a sealing paste is applied for sealing or optionally bonding the joints of the plate elements when assembling the crucible.

32. Method according to claim 17,
characterised in that
the powder mixture comprises more than 60 weight % silicon nitride particles and less than 40 weight % silicon particles,
the powder mixture is formed to an aqueous paste by adding high purity water, and
that the green bodies formed of the aqueous slurry are heated in an atmosphere of essentially pure nitrogen up to a temperature above 1400° C.

33. Method according to claim 18,
characterised in that
the powder mixture comprises more than 60 weight % silicon nitride particles and less than 40 weight % silicon particles,
the powder mixture is formed to an aqueous paste by adding high purity water and
that the green bodies formed of the aqueous slurry are heated in an atmosphere of essentially pure nitrogen up to a temperature above 1400° C.

34. Method according to claim 17,
characterised in that the green body is a shaped body of the silicon nitride powder and silicon powder mixture by use of one of the following: dry pressed powder mixtures containing only silicon and silicon nitride powder, or shaped objects consolidated form aqueous or non aqueous suspensions or slips by slip casting, gel casting or any other ceramic shaping method.

35. Method according to claim 18,
characterised in that the green body is a shaped body of the silicon nitride powder and silicon powder mixture by use of one of the following: dry pressed powder mixtures containing only silicon and silicon nitride powder, or shaped objects consolidated from aqueous or non aqueous suspensions or slips by slip casting, gel casting or any other ceramic shaping method.
